(19) United States
(12) Patent Application Publication
(10) Pub. No.: US 2019/0319157 A1
(43) Pub. Date: Oct. 17, 2019

(54) ELECTRONIC DEVICE COMPRISING ELECTRONIC CHIPS

(71) Applicants: STMicroelectronics (Grenoble 2) SAS, Grenoble (FR); STMicroelectronics Pte Ltd, Singapore (SG)

(72) Inventors: Romain COFFY, Voiron (FR); Laurent HERARD, Singapore (SG); David GANI, Singapore (SG)

(73) Assignees: STMicroelectronics (Grenoble 2) SAS, Grenoble (FR); STMicroelectronics Pte Ltd, Singapore (SG)

(21) Appl. No.: 16/378,153

(22) Filed: Apr. 8, 2019

(30) Foreign Application Priority Data
Apr. 13, 2018 (FR) 1853230

(51) Int. Cl. H01L 31/12; H01L 31/0203

(52) U.S. Cl. CPC H01L 31/125; H01L 31/0203

(57) ABSTRACT

A carrier wafer has a back face and a front face and a network of electrical connections between the back face and the front face. A first electronic chip is mounted with its bottom face on top of the front face of the carrier wafer. The first electronic chip has a through-opening extending between the bottom face and a face. A second electronic chip is installed in the through-opening and mounted to the front face of the carrier wafer.

### PRIORITY CLAIM

This application claims the priority benefit of French Application for Patent No. 1853230, filed on Apr. 13, 2018, the content of which is hereby incorporated by reference in its entirety to the maximum extent allowable by law.

### TECHNICAL FIELD

The present invention relates to the field of microelectronics and more particularly to the field of electronic devices including electronic chips.

### SUMMARY

In an embodiment, an electronic device comprises a carrier wafer having a back face and a front face and provided with a network of electrical connections, from one face to the other, a first electronic chip mounted on top of the front face of the carrier wafer and having a through-opening from one face to the other, and a second electronic chip located at least partly in said opening and mounted on top of the front face of the carrier wafer.

Thus, the footprint of the chips on the substrate can be decreased.

At least one electrical connection wire may be provided to connect at least one pad of the front face of the first chip and at least one pad of the front face of the second chip.

The first chip may comprise, in its front face, a light sensor and the second chip may comprise, in its front face, a light emitter.

According to one variant embodiment, a cover may be mounted on top of the carrier wafer and may define a chamber in which the light sensor and the light emitter are located, the cover potentially comprising a front wall having a through-opening provided with an optical element allowing light to pass through that is located above and facing the light emitter.

According to another variant embodiment, a cover may be mounted on top of the carrier wafer and may define two chambers separated by an interior partition, in which the light sensor and the light emitter are located, respectively, the cover comprising a front wall having through-openings provided with optical elements allowing light to pass through, which optical elements are located above and facing the light emitter and the light sensor, respectively.

The first chip may comprise, in its front face, first and second light sensors and the second chip may comprise, in its front face, a light emitter.

According to another variant embodiment, a cover may be mounted on top of the carrier wafer and may define first and second chambers that are separated by an interior partition through which the first chip passes, the light emitter and the first light sensor being located in the first chamber and the second light sensor being located in the second chamber, the cover comprising a front wall having a through-opening provided with an optical element allowing light to pass through, which optical element is located above the light emitter, and an opening provided with an optical element allowing light to pass through, which optical element is located above the second light sensor.

### BRIEF DESCRIPTION OF THE DRAWINGS

An electronic device will now be described by way of non-limiting exemplary embodiment, illustrated by the drawing, in which:

FIG. 1 shows a longitudinal section of the electronic device;

FIG. 2 shows a top view of the electronic device, along II-II marked in FIG. 1, the cover being in section; and

FIG. 3 shows a cross section of the electronic device, along III-III marked in FIG. 1.

### DETAILED DESCRIPTION

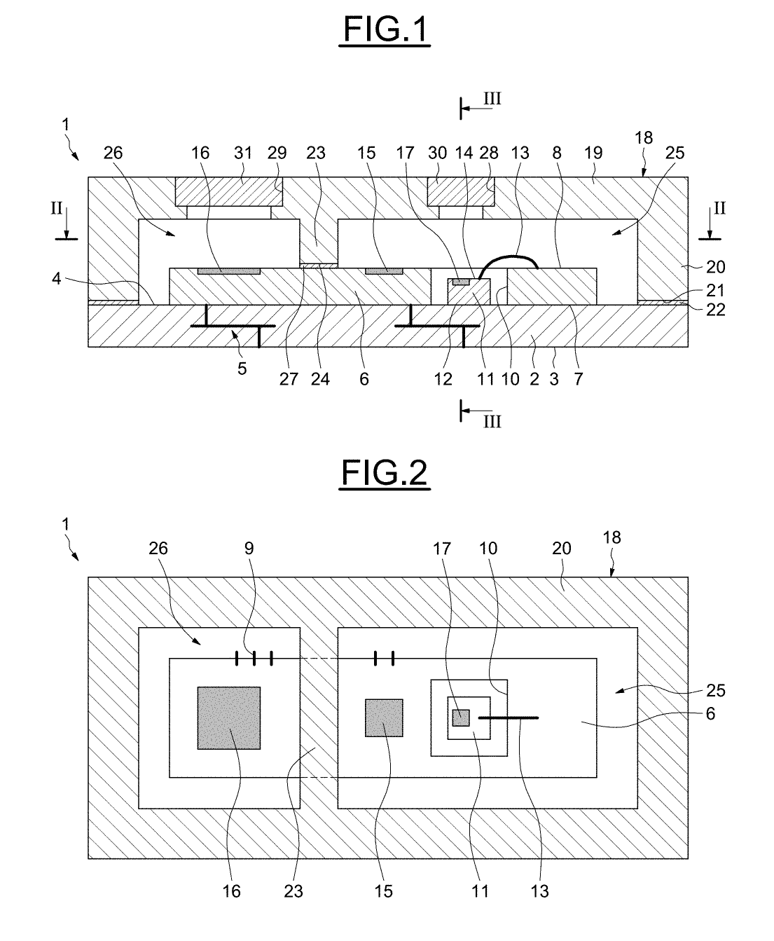

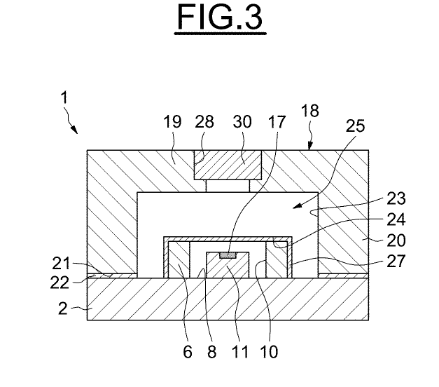

An electronic device 1, illustrated in FIGS. 1 to 3, comprises a main carrier wafer 2 made of a dielectric material, for example having a rectangular outline, which has a back face 3 and a front face 4 and which is provided with an integrated network 5 of electrical connections between front pads at the front face and back pads at the back face.

The electronic device 1 comprises a first electronic integrated circuit chip 6, for example having a rectangular outline, which has a back face 7 and a front face 8 and which is mounted on top of the front face 4 of the main carrier wafer 2 via a layer of adhesive interposed between the front face 4 of the main carrier wafer 2 and the back face 7 of the first chip 6.

The first chip 6 is connected to the network of electrical connections 5 by electrical connection wires 9 linking front pads of the first chip 6 to front pads of the main carrier wafer 2.

In a zone free from electronic components, the first chip 6 has an opening 10, which passes therethrough from one face to the other. The opening 10 may be made by laser drilling.

The electronic device 1 comprises a second electronic integrated circuit chip 11 which is located at least partly in the opening 10 and which is mounted on top of the front face 4 of the carrier wafer 2.

Thus, the footprint of the chips 6 and 11 on the substrate wafer 2 is reduced to the footprint of solely the first chip 6.

The second chip 11 may be connected to the network of electrical connections 5 of the main carrier wafer 2 by at least one direct joining between at least one back pad of the back face 12 of the second chip 11 and at least one front pad of the main carrier wafer 2 and/or may be connected to the first chip 6 by at least one electrical connection wire 13 linking at least one front pad of a front face 14 of the second chip 11 and at least one front pad of the front face 8 of the first chip 6. The electrical signals transmitted via the electrical wire 13 may be transmitted to the network of electrical connections 5 of the main carrier wafer 2 via the main chip 6.

According to one exemplary embodiment, the electronic device 1 comprises the following arrangements.

A longitudinal direction and a transverse direction are considered.

The front face 8 of the first chip 6 is provided with two light sensors 15 and 16, which are longitudinally spaced apart.

The front face 14 of the second chip 11 is provided with a light emitter 17.

The opening 10 of the first chip is located in the vicinity of and a distance away from the light sensor 15 of the first chip.

Advantageously, the light sensors 15 and 16 and the light emitter 17 are longitudinally aligned.

The electronic device 1 comprises a cover 18 that comprises a front or frontal wall 19 and a peripheral wall 20 which projects backwards from the front wall 19 and which has a back end face 21 located on top of a peripheral zone of the front face 4 of the main carrier wafer 2.

The cover 18 is attached to the main carrier wafer 2 via a bead of adhesive 22 interposed between the front face 8 of the main carrier wafer 2 and the back end face 38 of the peripheral wall 37.

The cover 18 comprises a transverse interior partition 23 which projects backwards from the front wall 19 and rejoins the longitudinal sides of the peripheral wall 20.

The interior partition 23 has a back notch 24 through which the first chip 6 passes and which defines two chambers 25 and 26 above the main carrier wafer 2, such that the light sensor 15 of the first chip 6 and the second chip 11 are located in the chamber 25 and that the light sensor 16 of the first chip 6 is located in the chamber 26.

A bead of adhesive 27 is interposed between the interior partition 23 and the first chip 6, in the notch 24, and between the interior partition 23 and the main carrier wafer 2, on either side of the first chip 6.

The frontal wall 19 of the cover 18 has through-openings 28 and 29 which are located facing the chambers 25 and 26 and which are provided with optical elements 30 and 31 through which light may pass, which optical elements take the shape of plates, for example. The optical elements 30 and 31 may bear against interior shoulders of the openings 28 and 29 and be bonded to the front wall 19 of the cover 18.

The optical element 30 is located above the light emitter 17. The optical element 31 is located above the light sensor 16.

The electronic device 1 may operate in the following way.

The light emitter 15 of the second chip 11 emits light, for example infrared, radiation outwards through the optical element 30.

The emitted light radiation, present in the chamber 25, is detected by the light sensor 15 of the first chip 6.

The light sensor 16 of the first chip 6 detects external light radiation through the optical element 31.

The electronic device 1 may constitute a detector for detecting the proximity of a body by processing the signals arising from the light sensors 30 and 31 or a camera.

By virtue of the various described arrangements, the electronic device 1 is particularly compact.

1. An electronic device, comprising:
a carrier wafer having a back face and a front face and provided with a network of electrical connections between the front face and the back face;
a first electronic chip having a bottom face mounted on top of the front face of the carrier wafer and having a through-opening from a top face to the bottom face; and
a second electronic chip located at least partly in said opening and having a first face mounted on top of the front face of the carrier wafer.

2. The device according to claim 1, wherein at least one pad of the top face of the first electronic chip and at least one pad of the second electronic chip are connected by at least one electrical connection wire.

3. The device according to claim 1, wherein the first electronic chip comprises a light sensor in the top face, and the second electronic chip comprises a light emitter in a second face opposite the first face.

4. The device according to claim 3, further comprising a cover mounted on top of the carrier wafer and defining a chamber in which the light sensor and the light emitter are located, the cover comprising a front wall having a through-opening provided with an optical element allowing light to pass through that is located above and facing the light emitter.

5. The device according to claim 3, further comprising a cover mounted on top of the carrier wafer and defining two chambers separated by an interior partition, with the light sensor located within one of the two chamber and the light emitter located in another of the two chambers, the cover comprising a front wall having through-openings provided with optical elements allowing light to pass through, wherein the optical elements are located above and facing the light emitter and the light sensor, respectively.

6. The device according to claim 1, wherein the first electronic chip comprises first and second light sensors in the top face and the second chip comprises a light emitter in a second face opposite the first face.

7. The device according to claim 6, further comprising a cover mounted on top of the carrier wafer and defining first and second chambers that are separated by an interior partition through which the first chip passes, the light emitter and the first light sensor being located in the first chamber and the second light sensor being located in the second chamber, the cover comprising a frontal wall having a first through-opening provided with an optical element that allows light to pass through and is located above the light emitter, and a second through-opening provided with an optical element that allows light to pass through and is located above the second light sensor.
